(19) United States
(12) Patent Application Publication
(10) Pub. No.: US 2007/0257265 A1
(43) Pub. Date: Nov. 8, 2007

(54) Use of tungsten interlayer to enhance the initial nucleation and conformality of ultrananocrystalline diamond (UNCD) thin films

(75) Inventors: Nevin N. Naguib, Aurora, IL (US); James Birrell, Chicago, IL (US); Jeffrey W. Elam, Elmhurst, IL (US); John A. Carlisle, Plainfield, IL (US); Orlando H. Auciello, Bolingbrook, IL (US)

Correspondence Address: Harry M. Levy, Esq.;Emrich & Dithmar, Suite 2080, 125 South Wacker Drive, Chicago, IL, 60606, US

(73) Assignee: The University of Chicago, Chicago, IL (US)

(21) Appl. No.: 11/429,016

(22) Filed: May 3, 2006

(51) Int. Cl. H01L 31/0312; H01L 21/00

(52) U.S. Cl. 257/77; 438/105

(57) ABSTRACT

Extremely smooth (6 nm roughness) and continuous ultrananocrystalline diamond (UNCD) thin films were achieved by microwave plasma chemical vapor deposition using a thin 10 nm tungsten (W) interlayer between the silicon (Si) substrate and the diamond film. The W interlayer significantly increased the initial UNCD nucleation density to >10¹² sites/cm², thereby lowering the surface roughness and eliminating interfacial voids. A method is also disclosed to make various articles.

### CONTRACTUAL ORIGIN OF THE INVENTION

The United States Government has rights in this invention pursuant to Contract No. W-31-109-ENG-38 between the U.S. Department of Energy and The University of Chicago representing Argonne National Laboratory.

### FIELD OF THE INVENTION

This invention relates to molding ultrananocrystalline diamond (UNCD) and

### BACKGROUND OF THE INVENTION

The surface chemistry and roughness of diamond thin films is critical in many applications including wear resistant low friction coatings, micro-electromechanical systems (MEMS) and bio-devices, see M. Moseler, P. Gumbsch, C. Casiraghi, A. C. Ferrari and J. Robertson, Science 309 1545 (2005) and A. Hartl, E. Schmich, J. Garrido, J. Hernando, S. C. R. Catharino, S. Walter, P. Feulner, A. Kromka, D. Steinmuller and M. Stutzmann, Nat. Mater. 3, 736 (2004). Although diamond thin films possess outstanding electrical, mechanical and thermal properties, the intrinsically high surface roughness is undesirable, see K. E. Spear, and J. P. Dismukes (Eds.), Synthetic Diamond; Emerging CVD Science and Technology, John Wiley and Sons, Inc., USA, (1993). Ultrananocrystalline diamond (UNCD) is an emerging form of diamond thin film characterized by 3-5 nm diameter grains and atomically abrupt (<0.2 nm) grain boundaries composed of disordered carbon bonded in sp², sp³, and other local bonding configurations, see A. R. Krauss, O. Auciello, D. M. Gruen, A. Jayatisa, A. Sumant, J. Tucek, D. C. Mancini, N. Moldovan, A. Erdemir, D. Ersoy, M. N. Gardos, H. G. Busmann, E. M. Meyer, and M. Q. Ding, Diamond. Relat. Mater. 10, 1952 (2001) and D. M. Gruen, Annu. Rev. Mater. Sci. 29, 211 (1999), incorporated herein. The fine grain size is a result of the high renucleation rate that occurs during growth using hydrogen-poor, argon-rich microwave plasma discharges, see J. E. Gerbi, J. Birrell, M. Sardela, and J. A. Carlisle, Thin Solid Films. 473, 41 (2005). Compared to conventional microcrystalline diamond films, UNCD films are inherently much smoother (20 nm RMS roughness) independent of film thickness, see A. Sumant, D. S. Grierson, J. E. Gerbi, J. Birrell, U. D. Lanke, O. Auciello, J. A. Carlisle and R. W. Carpick, Adv. Mater. 17, 1039 (2005). However, there is still a need to improve UNCD surface morphology, and reduce the surface roughness down to the intrinsic grain size of the material.

Several methods have been used to reduce the as-deposited surface roughness of diamond films, such as chemical mechanical polishing, see C. Y. Wang, F. L. Zhang, T. C. Kuang and C. L. Chen, Thin Sol. Films 496, 698 (2006) and 9-T. Takeno, T. Komoriya, I. Nakamori, H. Miki, T. Abe, T. Uchimoto, and T. Takagi, Diamond. Relat. Mater. 14, 2118 (2005), substrate biasing, see S-M. Huang, H-C. Hsu, M-S. You, and F. C-N. Hong, Diamond. Relat. Mater. 15, 22 (2006) and S-H Seo, T-H Lee, and J-S Park, Diamond. Relat. Mater. 12, 1670 (2003), and changing the deposition parameters during growth, see C. F. M. Borges, V. T. Airoldi, E. J. Corat, M. Moisan, S. Schelz, and D. Guay, J. Appl. Phys. 80, 10, 6013 (1996). So far, most of these methods are cost prohibitive and they may alter the bulk and surface properties of the diamond films. Therefore, there is still a need to reproducibly deposit very smooth and conformal thin diamond films, while enhancing the nucleation density and preserving the desirable properties.

The nucleation and initial growth of diamond thin films have been widely investigated, see J. Butler and H. Windischmann, Mater. Res. Soc. Bull. 23, 22 (1998) and F. G. Celii and J. E. Bulter, Annu Rev. Phys. Chem. 42, 643 (1991) and different seeding techniques have been established to enhance nucleation and achieve uniform continuous films, see H. Liu and D. S. Dandy, Diamond. Relat. Mater. 4, 1173 (1995), incorporated herein. For example, the new nucleation process (NNP) is a seeding technique in which the substrate is ultrasonically treated in an organic suspension of nanometer-sized diamond (ND) particles prior to diamond film growth resulting in high nucleation densities (10¹¹ sites/cm²). NNP has become a standard technique in many groups and has been used to enhance the growth of UNCD at low temperatures, see X. Xiao, J. Birrell, J. E. Gerbi, O. Auciello, and J. A. Carlisle, J. Appl. Phys. 96, 2232 (2004), incorporated herein. The “Rotter nucleation technique”, see S. Rotter, Proceedings of the Applied Diamond Conference/Frontier Carbon Technologies ADC/FCT '99, edited by M. Yoshikawa, Y. Koga, Y. Tzeng, C.-P. Klages, and K. Miyoshi, ˜MYU K. K., Tokyo, 25 (1999), requires high temperatures while bias, see S. Saada, S. Barrat, and E. Bauer-Grosse, Diamond. Relat. Mater. 10, 300 (2001), and chemical methods (including mechanical abrading, which is limited to flat surfaces), see A. Giraud, T. Jenny, E. Leroy, O. M. Kuttel, L. Schlapbach, P. Vanelle, and L. Giraud, J. Am. Chem. Soc., 123, 2271 (2001), have not been widely standardized due to their limitations. Thus, there is an urgent need to a standardized reproducible seeding technique that will enable diamond coating of different shapes with uniformity and continuity.

Metal interlayers have been used previously to promote adhesion of diamond thin films. For instance, U.S. Pat. No. 5,491,002 issued Feb. 13, 1996 to Slutz teaches the use of a refractory metal (Ti, Zr, Hf, V, Ni, Ta, Mo and W as an intermediate layer between two diamond layers to promote adhesion of the diamond layers. Diamond deposition on carbide-forming materials promotes adhesion, while diamond deposition on steel, copper or non-carbon affinity materials, which are carbon dissolving materials, leads to poor adhesion and non-uniformity.

### SUMMARY OF THE INVENTION

An important object of this invention is to provide a very smooth exposed UNCD surface on an article of manufacture and a method of making same.

Another object of the invention is to provide an ultrananocrystalline diamond (UNCD) structure having a first surface in contact with a substrate during formation and a second surface out of contact with a substrate during formation, the second surface having a RMS surface roughness less than about 10 nanometers (nm).

Another object of the invention is to provide a combination of UNCD and a thin tungsten layer in contact with at least a portion thereof, wherein the UNCD surface out of contact with the thin tungsten layer has a RMS surface roughness of less than about 10 nm.

A still further object of the invention is to provide a combination of a substrate having a thin tungsten layer on at least a portion thereof, and at least about 10¹² nucleation sites/cm² of diamond on at least a portion of the thin tungsten layer.

A final object of the invention is to provide a method of making an article having a free surface of UNCD with a RMS surface roughness less than 10 nm, comprising depositing a thin layer of tungsten on a substrate, optionally providing an aluminum oxide layer intermediate the substrate and the thin layer of tungsten, forming nucleation sites at a concentration of not less than about 10¹² nucleation sites/cm² of diamond on at least a portion of said thin tungsten layer, and thereafter growing UNCD on the nucleation sites providing an UNCD surface in contact with the tungsten and a free surface.

The invention consists of certain novel features and a combination of parts hereinafter fully described, illustrated in the accompanying drawings, and particularly pointed out in the appended claims, it being understood that various changes in the details may be made without departing from the spirit, or sacrificing any of the advantages of the present invention.

### BRIEF DESCRIPTION OF THE DRAWINGS

For the purpose of facilitating an understanding of the invention, there is illustrated in the accompanying drawings a preferred embodiment thereof, from an inspection of which, when considered in connection with the following description, the invention, its construction and operation, and many of its advantages should be readily understood and appreciated.

FIGS. 1(a)-(c) are SEM, AFM images and cross sectional SEM images of UNCD films deposited without W film added;

FIGS. 1(d)-(f) are SEM, AFM images and cross sectional SEM images of UNCD films deposited on a sputtered W film as a seed layer (100 Å thickness);

FIGS. 1(g)-(i) are SEM, AFM images and cross sectional SEM images of UNCD deposited on an ALD W seed layer (100 Å thickness) respectively. All films were grown for 20 minutes under the same deposition conditions;

FIG. 2(a)-(c) are SEM image comparisons of micro tip array coated with UNCD showing lower magnification images of the tip;

FIGS. 2(d)-(f) are SEM image comparisons showing higher magnification images of the tip. Images (a, d) are for the tip coated with UNCD without any tungsten seed layer. Images (b,e) are for UNCD deposited on a sputtered W seed layer and finally images (c,f) are for UNCD deposited on ALD W seed layer. A complete and uniform coverage is observed with the ALD W seed layer (f), compared to that of the sputtered or just plain surface (d and e).

FIG. 3 is a cross-sectional high resolution transmission electron microscope (HRTEM) image along with a qualitative elemental map of Si (Si-2p edge), W (W-4f edge) and C (C-1s edge) of the UNCD film deposited on an ALD W; and

FIG. 4 is a schematic representation of a combination of a substrate, a tungsten layer, a UNCD layer and an electrical element or a heating element or a piezo element or a biologically or chemically functionalized element.

### DESCRIPTION OF THE PREFERRED EMBODIMENT

UNCD films were deposited on bare and W coated Si wafers at 800° C. and a power of 1200 W using a commercial microwave plasma system. The deposition parameters were: Argon: 49.2 sccm; Methane: 0.8 sccm; pressure: 200 mbar; deposition time: 20 minutes. Prior to UNCD growth, the wafers were seeded by immersing in an organic suspension of nanocrystalline diamond (ND) powder in an ultrasonic bath as reported previously.

W films were deposited using RF magnetron sputtering and Atomic Layer Deposition (ALD). ALD offers the advantage of coating complex, non-planar surfaces with monolayer control over the W thickness. Sputtering was carried out using an RF power of 150 W and an Ar flow of 30 sccm (mTorr-range pressure) at room temperature. The W ALD was performed in a custom apparatus, see J. W. Elam, M. D. Groner, and S. M. George, ReV. Sci. Instrum. 73, 2981 (2002), according to a previously described method, see J. W Klaus, S. Ferro, and S. M. George, Thin Sol. Films 360, 145 (2000), incorporated herein, in which tungsten hexafluoride (WF₆) and disilane (Si₂H₆) vapors were alternately pulsed through the reaction chamber. To enhance the nucleation of the W ALD, a 1 nm ALD aluminum oxide (Al₂O₃) layer was deposited on the Si prior to W growth, see R. K. Grubbs, C. E. Nelson, N. J. Steinmetz, and S. M. George, Thin Sol. Films 16, 467 (2004). Although only tungsten layers were deposited, tungsten alloys wherein tungsten is the major constituent should also be applicable as are tungsten alloys wherein tungsten is present in about 90% by weight or more. While ALD is the preferred method of depositing tungsten, other well known methods such as vapor deposition, chemical vapor deposition, sputtering, evaporation or laser ablation are acceptable alternatives. Both Mo and Ti layers were substituted for tungsten, but the results were unsatisfactory.

UNCD thin films were characterized by scanning electron microscopy (SEM), atomic force microscopy (AFM) and transmission electron microscopy (TEM) techniques. SEM analysis was performed in a Hitachi S4700 field emission scanning electron microscope (FE-SEM) at a 10 kV accelerating voltage and a beam current of 10 μmA. AFM analysis was performed using a Digital Instruments Nanoscope-IV Controlled Multimode scanning probe microscope with 1-10 ohm-cm phosphorus (n) doped Si tips in tapping mode. TEM investigation was performed in a 200 keV field emission instrument (Tecnai 20F ST) equipped with a post-column energy filter (GATAN). TEM cross sectional samples were prepared by extracting lamella with a thickness of about 200 nm using a Focused Ion Beam (FIB, Zeiss XB). TEM samples were then sputtered with Ar ions (angle of 4° and 1 kV energy) to remove the surface layer damaged by the 30 keV Gallium ions of the FIB.

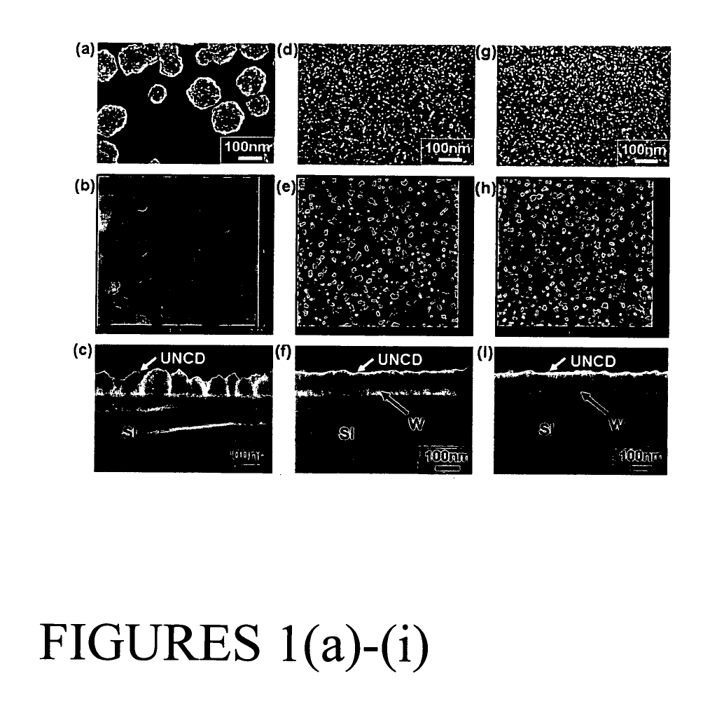

FIG. 1 compares UNCD deposited on plain Si versus UNCD deposited onto 10 nm W thin films on Si. The deposition time was 20 min. for each film. SEM images clearly show that UNCD films grown using an interfacial W layer (FIGS. 1d, 1g) are much denser and more uniform than those without the W layer (FIG. 1a). AFM analysis shows that UNCD on Si exhibits high roughness of about 20 nm as shown FIG. 1b. However, much smoother UNCD surfaces were achieved when deposited on sputtered W (FIG. 1e, 8.2 nm roughness) and ALD W (FIG. 1h, 6.3 nm roughness). Cross sectional SEM images reveal uniform UNCD films with a thickness of 107 nm when W was used as a seed layer (FIG. 1f and FIG. 1i), while UNCD islands (70 nm thickness) are formed without the W layer (FIG. 1c). Therefore, we conclude that W interlayer enhances the initial nucleation density (>10¹² sites/cm²), which in turn reduces the surface roughness and produces a uniform deposit requiring less time to coalesce into a continuous film.

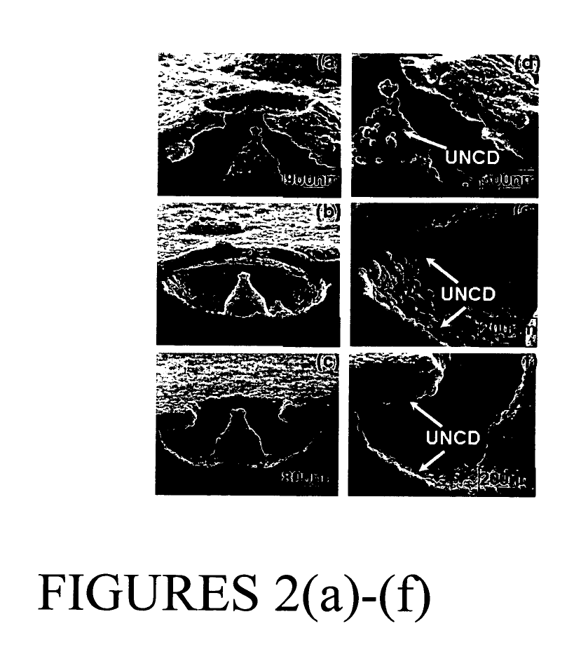

Both the sputtering and ALD W seed layers produce uniform, smooth UNCD films on planar Si surfaces. However, ALD W can be used to seed non-planar substrates such as micro-tip arrays (FIG. 2). Without a W seed layer, discontinuous UNCD is observed (FIGS. 2a, 2d). The UNCD uniformity improves using a sputtered W layer, however incomplete coverage is observed in shadowed regions of the substrate (FIGS. 2b, 2e) since sputtering is limited to line of sight. On the other hand, a uniform and conformal UNCD film was observed on the micro-tip array with the ALD W seed layer (FIG. 2c, 2f). The ALD W technique allows deposition of thin, conformal UNCD layers on all surfaces including shadowed regions. This W deposition technique is very much needed for diamond deposition on non-flat surfaces. Although silicon substrates were used, the invention includes any substrate, but preferably silicon or a silicon compound, such as but not limited to SiO₂. Thin layers of tungsten were deposited, preferably in the 300 to 600 nm range but thicknesses between about 100 to about 1000 nm are acceptable.

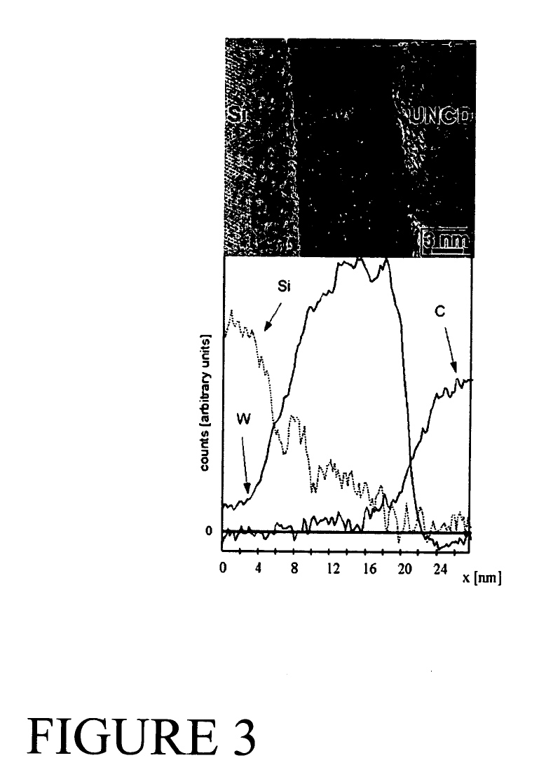

In order to investigate the Si—W-UNCD interfaces, energy filtering TEM (EFTEM) was performed on cross-sectional specimens of the UNCD film deposited on ALD W. Elemental line-scans with a resolution of 2 nm for Si (Si-2p edge), W (W-4f edge) and C (C-1s edge) along with a high resolution transmission electron microscopy (HRTEM) image are shown in FIG. 3. The amorphous region visible at the Si/W interface may be the Si native oxide, the 1 nm ALD nucleation layer, or possibly tungsten silicide (WSi₂). A significant amount of C can be detected in the W-layer up to a depth of 5 nm suggesting tungsten carbide formation or possibly C diffusion into the nano-crystalline W grain boundaries. Lattice distances measured from HRTEM images of the W-layer are consistent with pure W grown by ALD process. The as-deposited W layers are as smooth as the underlying silicon substrates, yet HRTEM shows a rough W/UNCD interface, which may also enhance UNCD initial nucleation.

It is not yet clear why the W interlayers promote smooth, uniform UNCD films. Previous investigations using different metal interlayers (Ti, Cr, and Mo) did not yield similar enhancements. Being a softer material than Si, W may reduce agglomeration of ND seeds on the surface, leading to a higher dispersion of the seeds. Compared to other metal carbides, tungsten carbide has a high thermal stability and a thermal expansion coefficient that is closely matched to CVD diamond see J. C. Arnault. Surf. Rev. Lett. 10, 127-146 (2003), and these properties may enhance the UNCD nucleation. It should be noted that without the ND seeding step, no UNCD is deposited. This argues that physical interactions between the ND seeds and the W surface are responsible for the enhanced UNCD nucleation.

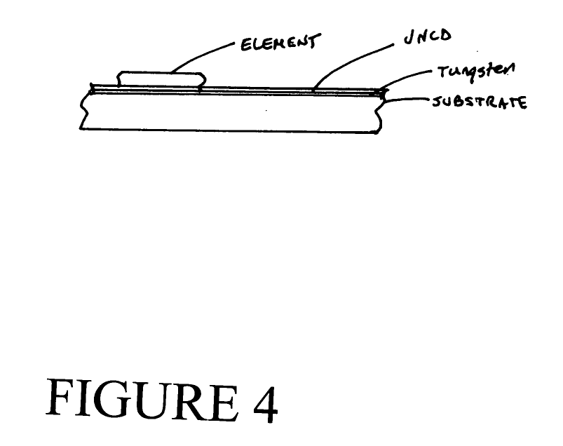

Referring to FIG. 4, there is disclosed a schematic representation of a fully dense UNCD films with RMS roughness of less than 10 nm in combination with a variety of elements, such as but not limited to micro-electrochemical system (MEMs) or a nano-electrochemical system (NEMs) or a complementary metal-oxide-semiconductor (CMOS) device.

To summarize, smooth, dense and continuous UNCD thin films were achieved by applying a W interlayer onto a Si substrate using either RF magnetron sputtering or ALD prior to the UNCD growth. ALD W allows complex non-planar substrates to be conformally coated with thin UNCD layers. The W seed layers significantly enhance the initial UNCD nucleation density (>10¹² sites/cm²) resulting in an RMS roughness of only 6-8 nm, and promote rapid coalescence so that continuous films are formed at very small thickness and very short time.

All cited articles or patents or applications are herein incorporated in their entireties.

While the invention has been particularly shown and described with reference to a preferred embodiment hereof, it will be understood by those skilled in the art that several changes in form and detail may be made without departing from the spirit and scope of the invention.

1. An ultrananocrystalline diamond (UNCD) structure having a first surface in contact with a substrate during formation and a second surface out of contact with a substrate during formation, said second surface having a RMS surface roughness less than about 10 nanometers (nm).

2. The structure of claim 1, wherein said second surface roughness is less than about 6 nm.

3. The structure of claim 1, wherein at least 95% of said UNCD has average grain sizes between about 2 and about 5 nm.

4. The structure of claim 1, wherein said UNCD second surface is integral with an UNCD substrate.

5. The structure of claim 1, wherein at least some of said UNCD is electrically conductive.

6. The structure of claim 1, wherein at least some of said UNCD is chemically or biologically functionalized.

7. The structure of claim 1, and further including an electrical element in communication therewith.

8. The structure of claim 1, and further including a piezoresistive element in communication therewith.

9. The structure of claim 1, and further including a heating element in communication therewith.

10. The structure of claim 1, wherein said UNCD is a conformal coating forming a hollow or solid structure.

11. The structure of claim 1, wherein said substrate is non-diamond.

12. The structure of claim 1, wherein said substrate is silicon.

13. The structure of claim 1, wherein said substrate is a silicon compound.

14. A combination of UNCD and a thin tungsten layer in contact with at least a portion thereof, wherein the UNCD surface out of contact with said thin tungsten layer has a RMS surface roughness of less than about 10 nm.

15. The combination of claim 14, wherein said thin tungsten layer is formed by atomic layer deposition (ALD).

16. The combination of claim 14, wherein said thin tungsten layer is formed by vapor deposition.

17. The combination of claim 14, wherein said thin tungsten layer is formed by chemical vapor deposition.

18. The combination of claim 14, wherein said thin tungsten layer is about 100 to about 1000 nm in thickness.

19. The combination of claim 14, wherein said thin tungsten layer is about 300 to about 600 nm in thickness.

20. A combination of a substrate having a thin tungsten layer on at least a portion thereof, and at least about 10¹² nucleation sites/cm² of diamond on at least a portion of said thin tungsten layer.

21. The combination of claim 20, and further including UNCD on the portion of tungsten having the nucleation sites thereon and an optional aluminum oxide layer intermediate said substrate and said tungsten layer.

22. The combination of claim 21, wherein the surface of said UNCD out of contact with said tungsten has a surface roughness of not greater than about 10 nm.

23. The combination of claim 21, wherein the surface of said UNCD out of contact with said tungsten has a surface roughness of not greater than about 6 nm.

24. The combination of claim 22, wherein said UNCD is in contact with one or more of an electrical element or a heating element or a piezo element or a biologically or chemically functionalized element.

25. The combination of claim 24, wherein said electrical element is one or more of a micro-electrochemical system (MEMs) or a nano-electrochemical system (NEMs) or a complementary metal-oxide-semiconductor (CMOS) device.

26. The combination of claim 20, wherein said tungsten layer is formed by ALD.

27. The combination of claim 20, wherein said tungsten layer is formed by vapor deposition.

28. A method of making an article having a free surface of UNCD with a RMS surface roughness less than 10 nm, comprising depositing a thin layer of tungsten on a substrate, optionally providing an aluminum oxide layer intermediate the substrate and the thin layer of tungsten, forming nucleation sites at a concentration of not less than about 10¹² nucleation sites/cm² of diamond on at least a portion of said thin tungsten layer, and thereafter growing UNCD on the nucleation sites providing an UNCD surface in contact with the tungsten and a free surface.

29. The method of claim 28, and further including selectively removing the substrate.

30. The method of claim 29, and further including selectively removing the tungsten layer.
